(19) United States
(12) Patent Application Publication
(10) Pub. No.: US 2022/0017781 A1
(43) Pub. Date: Jan. 20, 2022

(54) SILICON WAFER POLISHING COMPOSITION AND METHOD

(71) Applicant: CMC Materials, Inc., Aurora, IL (US)

(72) Inventors: Hiroshi KITAMURA, Tsu City (JP); Tsuyoshi MASUDA, Tsu City (JP); Yoshiyuki MATSUMURA, Kashihara (JP); Akihisa NAMIKI, Tsu-shi (JP); Takeshi SAITO, Tsu City (JP)

(21) Appl. No.: 17/379,279

(22) Filed: Jul. 19, 2021

Related U.S. Application Data
(60) Provisional application No. 63/053,867, filed on Jul. 20, 2020.

(51) Int. Cl. C09G 1/02; C09K 13/00; C09K 13/02; H01L 21/306

(52) U.S. Cl. CPC C09G 1/02; H01L 21/30625; C09K 13/02; C09K 13/00

(57) ABSTRACT

A chemical mechanical polishing composition for polishing a silicon wafer comprises, consists essentially of, or consists of a water based liquid carrier, colloidal silica particles dispersed in the liquid carrier, about 0.01 weight percent to about 2 weight percent of a dipolar aprotic solvent at point of use, and a pH in a range from about 8 to about 12. A method for polishing a silicon wafer may include contacting the wafer with the above described polishing composition, moving the polishing composition relative to the wafer, and abrading the wafer to remove silicon from the wafer and thereby polish the wafer.

### CROSS-REFERENCE TO RELATED APPLICATIONS

None.

### FIELD OF THE INVENTION

The disclosed embodiments relate to chemical mechanical polishing and more particularly relate to compositions and methods for polishing silicon wafers.

### BACKGROUND OF THE INVENTION

Silicon wafers used in electronic devices are commonly prepared from a single crystal silicon ingot that is first sliced into thin wafers using a diamond saw, lapped to improve flatness, and etched to remove subsurface damage caused by lapping. These wafers are then commonly polished in a two-step, double-sided process to remove nanotopography caused by etching and to achieve the desired thickness before the wafers are acceptable for use in electronic devices.

During wafer processing, hard laser marks are commonly formed on the back side of the wafer to display the wafer lot number for traceability. The rim of these hard laser marks is generally protruded from the wafer surface. Flatness control in the vicinity of these protrusions is challenging on both the front and back sides of the wafer during the double sided polishing process.

As transistor sizes continue to shrink, silicon wafer surface finish requirements, including roughness, nanotopography, and flatness have become increasingly stringent and more challenging to achieve. There is a need in the art for polishing compositions and methods for improved flatness control, particularly in the vicinity of the hard laser marks.

### BRIEF SUMMARY OF THE INVENTION

A chemical mechanical polishing composition for polishing a silicon wafer is disclosed. The polishing composition comprises, consists essentially of, or consists of a water based liquid carrier, colloidal silica particles dispersed in the liquid carrier, about 0.01 weight percent to about 2 weight percent of a dipolar aprotic solvent at point of use, and a pH in a range from about 8 to about 12. A polishing concentrate may include, for example, from about 0.2 to about 40 weight percent of the dipolar aprotic solvent.

A method for polishing silicon wafers is further disclosed. The method may include contacting a wafer with the above described polishing composition, moving the polishing composition relative to the wafer, and abrading the wafer to remove silicon from the wafer and thereby polish the wafer. A suitable method may alternatively and/or additionally include applying a dipolar aprotic solvent to the polishing pad prior to polishing the wafers.

### BRIEF DESCRIPTION OF THE DRAWINGS

For a more complete understanding of the disclosed subject matter, and advantages thereof, reference is now made to the following descriptions taken in conjunction with the accompanying drawings, in which:

FIG. 1A depicts a plot of hard laser mark peak height versus polishing batch count.

FIG. 1B depicts a plot of silicon polishing rate versus polishing batch count.

### DETAILED DESCRIPTION OF THE INVENTION

Chemical mechanical polishing compositions are disclosed. The polishing composition comprises, consists essentially of, or consists of a water based liquid carrier, colloidal silica particles dispersed in the liquid carrier, about 0.01 weight percent to about 2 weight percent of a dipolar aprotic solvent at point of use, and a pH in a range from about 8 to about 12. In one preferred embodiment the dipolar aprotic solvent is dimethyl sulfoxide and the polishing composition further comprises at least one tetraalkylammonium salt, at least one aminophosphonic acid, and at least one nitrogen containing heterocyclic compound. A polishing concentrate may include, for example, from about 0.2 to about 40 weight percent of the dipolar aprotic solvent.

Methods for polishing a silicon wafer are further disclosed. In one embodiment, a silicon wafer may be polished using one of the above described polishing compositions. In another embodiment, the disclosed methods may include contacting, wetting, or soaking a polishing pad with a dipolar aprotic solvent to obtain a wetted polishing pad. The method may optionally include rinsing the solvent from the pad prior to polishing. The method further includes contacting the wetted polishing pad with a polishing composition, moving the polishing composition relative to the wafer, and abrading the wafer to remove silicon from the wafer and thereby polish the wafer. For example, the dipolar aprotic solvent may include is dimethyl sulfoxide and the polishing composition may include colloidal silica particles dispersed in a liquid carrier, and least one tetraalkylammonium salt, at least one aminophosphonic acid, at least one nitrogen containing heterocyclic compounds and may be free of dipolar aprotic solvent.

The disclosed compositions and methods may provide various technical advantages and improvements over the prior art. For example, the disclosed compositions and methods may enable silicon wafers to be polishing with improved flatness. For example, the disclosed compositions and methods may provide for improved flatness on the periphery of a silicon wafer, such as in the vicinity of hard laser marks. The disclosed embodiments may further provide for improved/reduced pad break-in time.

The polishing composition generally contains abrasive particles suspended in a liquid carrier. The liquid carrier is used to facilitate the application of the abrasive particles and any optional chemical additives to the surface of the substrate to be polished (e.g., planarized). The liquid carrier comprises preferably consists of, or consists essentially of, deionized water.

The abrasive particles preferably include silica particle and/or alumina particles and most preferably include colloidal silica particles suspended in the liquid carrier. As used herein the term colloidal silica particles refers to silica particles that are prepared via a wet process rather than a pyrogenic or flame hydrolysis process which produces structurally different particles. The colloidal silica particles may be aggregated or non-aggregated. Non-aggregated particles are individually discrete particles that may be spherical or nearly spherical in shape, but can have other shapes as well (such as generally elliptical, square, or rectangular cross-sections). Aggregated particles are particles in which multiple discrete particles are clustered or bonded together to form aggregates having generally irregular shapes. Aggregated colloidal silica particles are disclosed, for example, in commonly assigned U.S. Pat. No. 9,309,442.

The colloidal silica particles may have substantially any suitable particle size. The particle size of a particle suspended in a liquid carrier may be defined in the industry using various means. For example, the particle size may be defined as the diameter of the smallest sphere that encompasses the particle and may be measured using a number of commercially available instruments, for example, including the CPS Disc Centrifuge, Model DC24000HR (available from CPS Instruments, Prairieville, La.) or the Zetasizer® available from Malvern Instruments®. The colloidal silica particles may have an average particle size of about 5 nm or more (e.g., about 10 nm or more, about 20 nm or more, about 30 nm or more, or about 40 nm or more). The colloidal silica particles may have an average particle size of about 200 nm or less (e.g., about 150 nm or less, about 120 nm or less, about 100 nm or less, or about 80 nm or less). Accordingly, the colloidal silica particles may have an average particle size in a range bounded by any two of the above endpoints. For example, the colloidal silica particles may have an average particle size in a range from about 5 nm to about 200 nm (e.g., from about 10 nm to about 200 nm, from about 20 nm to about 150 nm, or from about 30 nm to about 100 nm).

The polishing composition may include substantially any suitable amount of the colloidal silica particles. The polishing composition may include about 0.01 wt. % or more colloidal silica particles at point of use (e.g., about 0.02 wt. % or more, about 0.05 wt. % or more, about 0.1 wt. % or more, about 0.2 wt. % or more, or 0.5 wt. % or more). The polishing composition may also include about 20 wt. % or less of the colloidal silica particles at point of use (e.g., about 10 wt. % or less, about 5 wt. % or less, about 3 wt. % or less, or about 2 wt. % or less). Accordingly, the point of use amount of silica particles in the polishing composition may be in a range bounded by any two of the above endpoints. For example, the amount of colloidal silica particles in the polishing composition may be in a range from about 0.01 wt. % to about 20 wt. % (e.g., from about 0.02 wt. % to about 10 wt. %, from about 0.05 wt. % to about 5 wt. %, from about 0.1 wt. % to about 3 wt. %, or from about 0.1 wt. % to about 2 wt. %).

The colloidal silica particles in the disclosed polishing compositions may include substantially any suitable surface charge. The charge on dispersed particles such as silica particles is commonly referred to in the art as the zeta potential (or the electrokinetic potential). The zeta potential of the colloidal silica particle may be positive (cationic) or negative (anionic). The disclosed embodiments are not limited in this regard.

The polishing composition may further include substantially any suitable dipolar aprotic solvent. It will be understood by those of ordinary skill in the chemical arts that a dipolar aprotic solvent is a solvent with a comparatively high relative permittivity or dielectric constant (e.g., greater than about 15) and a sizable permanent dipole moment that cannot donate labile hydrogen atoms to form strong hydrogen bonds (see IUPAC, Compendium of Chemical Terminology, 2nd ed., the “Gold Book”, 1997). Preferred dipolar aprotic solvents may include acetonitrile, dimethyl sulfoxide, dimethylformamide, hexamethylphosphoramide, ethyl acetate, pyridine, and mixtures thereof. Dimethyl sulfoxide is a most preferred dipolar aprotic solvent.

The polishing composition may include substantially any suitable amount of the dipolar aprotic solvent (e.g., dimethyl sulfoxide). The polishing composition may include about 0.001 wt. % or more (10 ppm by weight or more) of the dipolar aprotic solvent at point of use (e.g., about 0.01 wt. % or more, about 0.02 wt. % or more, 0.03 wt. % or more, or about 0.05 wt. % or more). The polishing composition may also include about 10 wt. % or less of the of the dipolar aprotic solvent at point of use (e.g., about 5 wt. % or less, about 3 wt. % or less, about 2 wt. % or less, or about 1 wt. % or less). Accordingly, the point of use concentration of the dipolar aprotic solvent in the polishing composition may be in a range bounded by any two of the above endpoints. For example, the amount of colloidal silica particles in the polishing composition may be in a range from about 0.001 wt. % to about 10 wt. % (e.g., from about 0.01 wt. % to about 5 wt. %, from about 0.02 wt. % to about 3 wt. %, from about 0.02 wt. % to about 2 wt. %, or from about 0.05 wt. % to about 1 wt. %).

The polishing composition has a pH of about 12 or less at point of use (e.g., about 11.5 or less or about 11 or less). The polishing composition may also have a pH of about 7 or more at point of use (e.g., about 8 or more, 8.5 or more, or 9 or more). Preferably, the polishing composition has a pH of about 7 to about 12 at point of use (e.g., about 8 to about 12, about 9 to about 12, about 7 to about 11, about 8 to about 11, or about 9 to about 11).

The polishing composition optionally includes pH adjusting agents, for example, potassium hydroxide, ammonium hydroxide, and/or nitric acid (depending, for example, on the desired pH). The polishing composition may also optionally include a pH buffering system, many of which are well-known in the art, e.g., including bicarbonate-carbonate buffer systems, aminoalkylsulfonic acids, and the like. The polishing composition may include any suitable amount of a pH adjustor and/or a pH buffering agent in order to achieve and/or maintain a desired pH (in either or both of a concentrate or point of use composition).

The polishing composition may optionally include other compounds, for example, including (i) one or more organic carboxylic acids, (ii) one or more polyaminocarboxylic acids, (iii) one or more aminophosphonic acids, (iv) one or more tetraalkylammonium salts, (iv) one or more amines, (v) one or more nitrogen containing heterocyclic compounds, and/or (vi) one or more bicarbonate salts. The polishing composition may further include a suitable amount of potassium hydroxide to achieve the preferred alkaline pH.

For example, the polishing composition may optionally include one or more carboxylic acids or salts thereof. Suitable organic carboxylic acid may include an alkyl carboxylic acid or aryl carboxylic acid and may be optionally substituted with groups selected from the group consisting of C₁-C₁₂ alkyl, amino, substituted amino (e.g., methylamino, dimethylamino, and the like), hydroxyl, halogen, and combinations thereof. Non-limiting examples of suitable carboxylic acids include malonic acid, lactic acid, malic acid, tartaric acid, acetohydroxamic acid, glycolic acid, 2-hydroxybutyric acid, benzilic acid, salicylic acid, 2,6-dihydroxybenzoic acid, glycine, alanine, proline, lysine, cysteine, leucine, aspartic acid, glutamic acid, 2-amino-4-thiazolacetic acid, 3-aminosalicylic acid 3-amino-4-hydroxybenzoic acid, picolinic acid, and nicotinic acid.

In embodiments including one or more organic carboxylic acids or salts, the polishing composition may include about 10 ppm by weight or more of the organic carboxylic acid at point of use (e.g., about 50 ppm by weight or more, about 100 ppm by weight or more, about 200 ppm by weight or more, or about 500 ppm by weight or more). The polishing composition may also include about 1 wt. % or less of the organic carboxylic acid at point of use (e.g., about 0.8 wt. % or less, about 0.5 wt. % or less, about 0.3 wt. % or less, or about 0.2 wt. % or less). Accordingly, the point of use amount of organic carboxylic acid in the polishing composition may be bounded by any two of the above endpoints. For example, the polishing composition may include about 10 ppm by weight (0.001 wt. %) to about 1 wt. % of the organic carboxylic acid at point of use (e.g., from about 50 ppm by weight to about 0.5 wt. %, or from about 200 ppm by weight to about to about 0.2 wt. %).

The polishing composition may optionally include one or more suitable polyaminocarboxylic acids or salts. The term polyaminocarboxylic as used herein refers to a compound having two or more amino groups and two or more carboxylic acid groups. Preferred polyaminocarboxylic acids are selected from the group consisting of ethylenediaminetetraacetic acid, diethylenetriaminepentaacetic acid, N-(hydroxyethyl)ethylenediaminetriacetic acid, nitrilotriacetic acid, methylglycinediacetic acid, salts thereof, and combinations thereof. Most preferred polyaminocarboxylic acids are selected from the group consisting of ethylenediaminetetraacetic acid, diethylenetriaminepentaacetic acid, salts thereof (e.g., a mono-, di-, tri-, or tetrasodium salt thereof), and mixtures thereof.

In embodiments including one or more polyaminocarboxylic acids or salts, the polishing composition may include about 5 ppm by weight or more of the polyaminocarboxylic acid at point of use (e.g., about 10 ppm by weight or more, about 20 ppm by weight or more, or about 50 ppm by weight or more). The polishing composition may also include about 0.5 wt. % (5000 ppm by weight) or less of the polyaminocarboxylic acid at point of use (e.g., about 0.3 wt. % or less, 0.2 wt. % or less, or about 0.1 wt. % or less). Accordingly, the point of use amount of the polyaminocarboxylic acid(s) in the polishing composition may be bounded by any two of the above endpoints. For example the polishing composition can include about 5 ppm by weight to about 0.5 wt. % of the polyaminocarboxylic acid(s) (e.g., about 10 ppm by weight to about 0.3 wt. %, about 20 ppm by weight to about 0.2 wt. %, or about 50 ppm by weight to about 0.1 wt. %).

The polishing composition may optionally include one or more suitable aminophosphonic acids. A suitable aminophosphonic acid may be selected, for example, from the group consisting of ethylenediaminetetra(methylene phosphonic acid), amino tri(methylene phosphonic acid), diethylenetriaminepenta(methylene phosphonic acid), salts thereof, and combinations thereof. One preferred aminophosphonic acid is amino tri(methylene phosphonic acid).

In embodiments including one or more aminophosphonic acid(s), the polishing composition may include about 20 ppm by weight or more of the aminophosphonic acid at point of use (e.g., about 50 ppm by weight or more, about 100 ppm by weight or more, about 200 ppm by weight or more, or about 500 ppm by weight or more). The polishing composition may also include about 0.5 wt. % or less of the aminophosphonic acid at point of use (e.g., about 0.3 wt. % or less, 0.2 wt. % or less, or about 0.1 wt. % or less). Accordingly, the polishing composition may include a point of use amount of aminophosphonic acid(s) bounded by any two of the above endpoints. For example, the polishing composition may include about 20 ppm by weight (0.002 wt. %) to about 0.5 wt. % of the aminophosphonic acid(s) (e.g., about 50 ppm by weight to about 0.3 wt. %, about 100 ppm by weight to about 0.2 wt. %, or about 200 ppm by weight to about 0.2 wt. %).

The polishing composition may optionally include one or more suitable tetraalkylammonium salt(s). Preferred tetraalkylammonium salts include a cation selected from the group consisting of tetramethylammonium, tetraethylammonium, tetrapropylammonium, and tetrabutylammonium. The tetraalkylammonium salts may include substantially any suitable anion such as, but not limited to, hydroxide, chloride, bromide, sulfate, or hydrogensulfate. In one preferred embodiment, a tetraalkylammonium salt may include tetraalkylammonium hydroxide (e.g., tetramethylammonium hydroxide).

In embodiments including one or more tetraalkylammonium salt(s), the polishing composition may include about 10 ppm or more by weight (0.001 wt. %) or more of the tetraalkylammonium salt at point of use (e.g., about 0.01 wt. % or more, about 0.02 wt. % or more, or about 0.05 wt. % or more). The polishing composition may also include about 2 wt. % or less of the tetraalkylammonium salt at point of use (e.g., about 1 wt. % or less, about 0.5 wt. % or less, or about 0.3 wt. % or less). Accordingly, the polishing composition may include a point of use amount of tetraalkylammonium salt(s) in an amount bounded by any two of the above endpoints. For example, the polishing composition may include about 0.001 wt. % to about 2 wt. % of the tetraalkylammonium salt(s) (e.g., about 0.01 wt. % to about 1 wt. %, about 0.02 wt. % to about 1 wt. %, or about 0.05 wt. % to about 1 wt. %).

The polishing composition may optionally include one or more suitable amines. Non-limiting examples of suitable amines include piperazine, aminoethylpiperazine, 2-methyl-2-aminoethanol, (2-aminoethyl)-2-aminoethanol, ethanolamine, diethanolamine, triethanolamine, ethylenediamine, diethylenetriamine, tetraethylenepentamine, hydrazine, 2-hydroxyethylhydrazine, semicarbazide, hydroxylamine, N-methylhydroxylamine, O-methylhydroxylamine, and O-carboxymethylhydroxylamine. Preferred amines include piperazine and/or aminoethylpiperazine.

In embodiments including one or more amines, the polishing composition may include about 0.01 wt. % or more of the amine(s) at point of use (e.g., about 0.02 wt. % or more, about 0.03 wt. % or more, or about 0.05 wt. % or more). The polishing composition may also include about 2 wt. % or less of the amine(s) at point of use (e.g., about 1.5 wt. % or less, about 1 wt. % or less, about 0.8 wt. % or less, or about 0.5 wt. % or less). Accordingly, the polishing composition may include a point of use concentration of amines in an amount bounded by any two of the above endpoints. For example, the polishing composition may include about 0.01 wt. % to about 2 wt. %, about 0.02 wt. % to about 1.5 wt. %, or about 0.02 wt. % to about 1 wt. % of the amine(s).

The polishing composition may optionally include one or more suitable nitrogen-containing heterocyclic compounds. The term nitrogen-containing heterocyclic compound as used herein refers to a 5-, 6-, or 7-membered ring compound having one or more nitrogen atoms contained as part of the ring system (structure). For example, in one embodiment, the nitrogen-containing heterocyclic compound may include a triazole such as an 1,2,3-triazole or 1,2,4-triazole or an aminotriazole such as 3-amino-1,2,4-triazole, 3-amino-1,2,4-triazole-5-carboxylic acid, 3-amino-5-mercapto-1,2,4-triazole, and 4-amino-5-hydrazino-1,2,4-triazole-3-thiol. In other embodiments, the nitrogen-containing heterocyclic compound may include a thiazole such as 2-amino-5-methylthiazole, 2-amino-4-thoazoleacetic acid, and thiazole. In still other another embodiments, the nitrogen-containing heterocyclic compound may include a heterocyclic N-oxide such as 2-hydroxypyridine-N-oxide, 4-methylmorpholine-N-oxide, and picolinic acid N-oxide. While the disclosed embodiments are not limited in this regard, triazoles such as 1,2,3-triazole or 1,2,4-triazole are generally preferred.

In embodiments including one or more nitrogen-containing heterocyclic compounds, the polishing composition can contain about 1 ppm by weight or more of the heterocyclic compound at point of use (e.g., 2 ppm by weight or more, 5 ppm by weight or more, or about 10 ppm by weight or more). The polishing composition may also include about 0.5 wt. % or less of the heterocyclic compound at point of use (e.g., about 0.2 wt. % or less, about 0.1 wt. % or less or about 0.05 wt. % or less, or about 0.02 wt. % or less). Accordingly, the polishing composition may include a point of use amount of the nitrogen-containing heterocyclic compound(s) in an amount bounded by any two of the above endpoints. For example the polishing composition may include about 1 ppm by weight to about 0.5 weight percent (e.g., about 2 ppm by weight to about 0.2 wt. %, about 5 ppm by weight to about 0.1 wt. %, or about 10 ppm by weight to about 0.05 wt. %) of the nitrogen-containing heterocyclic compound(s).

The polishing composition may optionally include one or more bicarbonate salts, for example, including potassium bicarbonate, sodium bicarbonate, ammonium bicarbonate, and combinations thereof. Polishing compositions including bicarbonate may include substantially any suitable amount at point of use, for example, about 10 ppm by weight to about 1 wt. %, about 20 ppm to about 0.5 wt. %, or about 50 ppm to about 0.5 wt. %.

The polishing composition may optionally include potassium hydroxide to adjust the pH. The amount of potassium hydroxide generally depends on the amount of other compounds (if any) in the polishing composition. For example, polishing compositions including potassium hydroxide may include about 10 ppm by weight to about 1 wt. %, about 20 ppm to about 0.5 wt. %, or about 50 ppm to about 0.5 wt. % at point of use.

The polishing composition may optionally further include a biocide. The biocide may include any suitable biocide, for example an isothiazolinone biocide. The amount of biocide in the polishing composition typically is in a range from about 1 ppm to about 50 ppm at point of use or in a concentrate, and preferably from about 1 ppm to about 20 ppm.

The polishing composition may be prepared using any suitable techniques, many of which are known to those skilled in the art. The polishing composition may be prepared in a batch or continuous process. Generally, the polishing composition may be prepared by combining the components (e.g., including the abrasive particles and optional compounds described above) thereof in any order. The term “component” as used herein includes the individual ingredients (e.g., the silica particles, the dipolar aprotic solvent, and other optional compounds).

For example, various polishing composition components (such as the dipolar aprotic solvent and a biocide) may be added directly to a dispersion including a suspended silica abrasive. The components may be blended together using any suitable techniques for achieving adequate mixing. Such blending/mixing techniques are well known to those of ordinary skill in the art. The polishing composition may advantageously be supplied as a one-package system including the comprising a colloidal silica having the above described physical properties and other optional components.

It will be understood that the dipolar aprotic solvent may be added at any time during the preparation of the polishing composition. The dipolar aprotic solvent may be provided as part of the above described one-package system (including the abrasive particles, the dipolar aprotic solvent, and other optional compounds). Alternatively, the dipolar aprotic solvent may be supplied separately from the other components of the polishing composition and may be combined, e.g., by the end-user, with the other components of the polishing composition shortly before use (e.g., within about 1 minute, or within about 10 minutes, or within about 1 hour, or within about 1 day, or within about 1 week of the polishing operation). The polishing composition also may also be prepared by mixing the components at the surface of the wafer (e.g., on the polishing pad) during the polishing operation. Various other two-container, or even three or more container, combinations of the components of the polishing composition are within the knowledge of one of ordinary skill in the art.

The polishing composition of the invention may also be provided as a concentrate which is intended to be diluted with an appropriate amount of water prior to use. In such an embodiment, the polishing composition concentrate may include the abrasive particles and other optional components such as a tetraalkylammonium salt, a polyaminocarboxylic acid, a nitrogen containing heterocyclic compounds, and/or a biocide with or without the dipolar aprotic solvent, in amounts such that, upon dilution of the concentrate with an appropriate amount of water, and the dipolar aprotic solvent if not already present in an appropriate amount, each component of the polishing composition will be present in the polishing composition in an amount within the appropriate ranges recited above for each component. For example, each of the components may each be present in the polishing composition in an amount that is about 2 times (e.g., about 3 times, about 4 times, about 5 times, about 10 times, about 15 times, or even about 20 times) greater than the point of use concentrations recited above for each component so that, when the concentrate is diluted with an equal volume (or mass) of water (e.g., 2 equal volumes (or masses) of water, 3 equal volumes (or masses) of water, 4 equal volumes (or masses) of water, 9 equal volumes (or masses) of water, 14 equal volumes (or masses) of water, or 19 equal volumes (or masses) of water respectively), each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

In one example embodiment, a polishing concentrate may include a water based liquid carrier, abrasive particles (e.g., at least 10 weight percent colloidal silica particles) dispersed in the liquid carrier, about 0.2 weight percent to about 40 weight percent of a dipolar aprotic solvent, and a pH in a range from about 8 to about 12. The polishing concentrate may be diluted with deionized water prior to use to obtain a polishing composition including 0.01 weight percent to about 2 weight percent of the dipolar aprotic solvent.

In certain embodiments it may be advantageous to dilute a polishing concentrate that is free of dipolar aprotic solvent with a mixture of water and dipolar aprotic solvent to obtain a polishing composition including about 0.01 weight percent to about 2 weight percent of the dipolar aprotic solvent. For illustration purposes only, one part of a polishing concentrate including 21 weight percent colloidal silica may be diluted with 20 parts of mixture including 5 weight percent dipolar aprotic solvent in water to obtain a polishing composition including 1 weight percent colloidal silica and 0.24 weight percent dipolar aprotic solvent. The disclosed embodiments are of course not limited in these regards or to any particular level of concentrate.

The polishing method of the invention is particularly suited for use in conjunction with a chemical mechanical polishing (CMP) apparatus. Silicon wafers are commonly polished using a double-sided polishing operation with an apparatus including upper and lower platens (although the disclosed embodiments are expressly not limited in this regard). In such double-sided operations, a polishing pad may be affixed to each platen. A carrier plate (or wafer holder) having at least one hole for holding the wafer(s) is interposed between the platens. The platens rotate independently and cause rotation of the carrier plate(s) thereby causing the wafer(s) to move relative to polishing surfaces of the polishing pads. Polishing of the wafer(s) takes place as the wafer(s) are contacted by the polishing pads (upper and lower) and the polishing composition of the invention and then the polishing pads moving relative to the silicon wafers so as to abrade at least a portion of both sides of the silicon wafer.

A substrate can be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof.

In alternative method embodiments, the dipolar aprotic solvents (e.g., the dimethyl sulfoxide) may be applied to the polishing pad prior to polishing. For example, the polishing pads (upper and/or lower) may be contacted with the dipolar aprotic solvent prior to polishing (e.g., about 1 minute, about 2 minutes, about 5 minutes, about 10 minutes, about 20 minutes, about 30 minutes, or about 1 hour prior to polishing). In one embodiment, the upper and lower pads are contacted with the dipolar aprotic solvent to obtain wetted or soaked pads (e.g., the solvent may be dispensed on the lower pad and then the upper pad lowered into contact with the lower pad and solvent). The pads may then be optionally rinsed with deionized water prior to polishing the silicon wafer(s). The wetted or rinsed pads may then be contacted with a polishing composition and moved relative to the wafers to thereby abrade and polish the wafers. The solvent may optionally be removed (e.g., rinsed off or spun off) the pads prior at introducing the polishing composition. In such embodiments, the polishing composition may be free of the dipolar aprotic solvent.

In certain desirable embodiments, the disclosed polishing compositions and methods improve the flatness of polished silicon wafers and the break-in time of the polishing pads.

It will be understood that the disclosure includes numerous embodiments. These embodiments include, but are not limited to, the following embodiments.

In a first embodiment a chemical mechanical polishing composition includes an aqueous based liquid carrier; abrasive particles dispersed in the liquid carrier; about 0.01 weight percent to about 2 weight percent of a dipolar aprotic solvent; and a pH in a range from about 8 to about 12.

A second embodiment includes the first embodiment wherein the dipolar aprotic solvent is a member of the group consisting of acetonitrile, dimethyl sulfoxide, dimethylformamide, hexamethylphosphoramide, ethyl acetate, pyridine, and mixtures thereof.

A third embodiment includes any one of the first through second embodiments wherein the dipolar aprotic solvent is dimethyl sulfoxide.

A fourth embodiment includes any one of the first through third embodiments comprising from about 1 weight percent to about 10 weight percent of the dipolar aprotic solvent.

A fifth embodiment includes any one of the first through fourth embodiments further comprising one or more organic carboxylic acids.

A sixth embodiment includes any one of the first through fifth embodiments further comprising one or more polyaminocarboxylic acids.

A seventh embodiment includes any one of the first through sixth embodiments further comprising one or more tetraalkylammonium salts.

An eighth embodiment includes any one of the first through seventh embodiments further comprising one or more aminophosphonic acids.

A ninth embodiment includes any one of the first through eighth embodiments further comprising one or more nitrogen containing heterocyclic compounds.

A tenth embodiment includes any one of the first through ninth embodiments, wherein the abrasive particles comprise colloidal silica abrasive particles.

An eleventh embodiment includes any one of the first through tenth embodiments further comprising: one or more tetraalkylammonium salts; one or more polyaminocarboxylic acids; and one or more nitrogen containing heterocyclic compounds.

A twelfth embodiment includes any one of the first through eleventh embodiments further comprising at least one of potassium hydroxide and potassium bicarbonate.

A thirteenth embodiment includes the any one of the first through twelfth embodiments wherein the dipolar aprotic solvent is dimethyl sulfoxide.

A fourteenth embodiment includes a method of chemical mechanical polishing a wafer, the method including (a) contacting the wafer with the polishing composition of any one of the first through thirteenth polishing composition embodiments; (b) moving the polishing composition relative to the wafer; and (c) abrading the wafer to remove silicon from the wafer and thereby polish the wafer.

A fifteenth embodiment includes the fourteenth embodiment wherein the method uses a polishing apparatus having (i) an upper platen and a lower platen, each of said platens having a polishing pad adhered thereto, and (ii) a carrier plate having at least one holding hole for holding the wafer; and said abrading in (c) removes silicon from opposing first and second sides of the wafer, thereby polishing the wafer.

A sixteenth embodiment includes any one of the fourteenth through fifteenth embodiments wherein the wafer includes a hard laser mark and said abrading in (c) improves a flatness of the wafer in a peripheral region of the wafer.

In a seventeenth embodiment a method of polishing a silicon wafer includes (a) providing a polishing apparatus having at least one polishing pad mounted on a corresponding platen; (b) contacting the polishing pad with a dipolar aprotic solvent to wet the polishing pad; (c) contacting said wetted polishing pad with a polishing composition; (d) moving the polishing composition relative to the wafer; and (e) abrading the wafer to remove silicon from the wafer and thereby polish the wafer.

An eighteenth embodiment includes the seventeenth embodiment wherein the polishing composition is free of dipolar aprotic solvent.

A nineteenth embodiment includes any one of the seventeenth through eighteenth embodiments wherein the dipolar aprotic solvent is dimethyl sulfoxide.

A twentieth embodiment includes any one of the seventeenth through nineteenth embodiments wherein the polishing composition comprises colloidal silica particles dispersed in an aqueous liquid carrier; one or more tetraalkylammonium salts; one or more polyaminocarboxylic acids; one or more nitrogen containing heterocyclic compounds; and a pH in a range from about 8 to about 12.

A twenty-first embodiment includes any one of the seventeenth through twentieth embodiments wherein: the polishing apparatus comprises (i) an upper platen and lower platen, each of said platens having a polishing pad adhered thereto, and (ii) a carrier plate having at least one holding hole for holding the wafer; and said abrading in (e) removes silicon from opposing first and second sides of the wafer, thereby polishing the wafer.

A twenty-second embodiment includes any one of the seventeenth through twenty-first embodiments wherein: the wafer includes a hard laser mark; and contacting the polishing pad with the dipolar aprotic solvent in (c) and abrading the wafer in (e) improves a flatness of the wafer in a peripheral region of the wafer.

A twenty-third embodiment includes any one of the seventeenth through twenty-second embodiments wherein (b) further comprises rinsing said wetted pad with deionized water prior to said contacting in (c).

In a twenty-fourth embodiment a chemical mechanical polishing concentrate includes a water based liquid carrier; abrasive particles dispersed in the liquid carrier; about 0.2 weight percent to about 40 weight percent of a dipolar aprotic solvent; and a pH in a range from about 8 to about 12. The polishing concentrate may optionally further include any one or more of the components disclosed in the fifth through the twelfth embodiments.

A twenty-fifth embodiment includes the twenty-fourth embodiment, wherein the abrasive particles comprise colloidal silica particles and the polishing concentrate comprises at least 10 weight percent of the colloidal silica particles.

In a twenty-sixth embodiment a method of chemical mechanical polishing a wafer includes (a) providing a polishing concentrate including: (i) a water based liquid carrier, (ii) at least 5 weight percent colloidal silica particles dispersed in the liquid carrier; and (iii) a pH in a range from about 8 to about 12; (b) diluting the polishing concentrate provided in (a) to obtain a polishing composition by adding at least 4 parts of a mixture of water and a dipolar aprotic solvent to 1 part of the polishing concentrate such that the polishing composition includes about 0.01 weight percent to about 2 weight percent of the dipolar aprotic solvent; (c) moving the polishing composition relative to the wafer; and (d) abrading the wafer to remove silicon from the wafer and thereby polish the wafer.

A twenty-seventh embodiment includes the twenty-sixth embodiment, wherein the method uses a polishing apparatus having (i) an upper platen and a lower platen, each of said platens having a polishing pad adhered thereto, and (ii) a carrier plate having at least one holding hole for holding the wafer; and said abrading in (c) removes silicon from opposing first and second sides of the wafer, thereby polishing the wafer.

The following examples further illustrate the invention but, of course, should not be construed as in any way limiting its scope.

### Example 1

This example demonstrates the effect of a dipolar aprotic solvent on the hard laser mark peak height. Three sets of silicon wafers were polished. Comparative Example 1A and Inventive Example 1C made use of SP2600 polishing slurry (available from Cabot Microelectronics) diluted with 20 parts by weight deionized water to 1 part by weight SP2600 polishing slurry to obtain a polishing composition having 1 weight percent silica abrasive. Inventive Example 1B made use of SP2600 polishing slurry diluted with sufficient deionized water and dimethyl sulfoxide to obtain a polishing composition having 1 weight percent silica abrasive and 0.24 weight percent dimethyl sulfoxide. In inventive Example 1C the mounted polishing pad was wet with dimethyl sulfoxide for 40 minutes prior to initiating the polishing experiment. The pad was flushed with deionized water for 5 minutes prior to polishing.

Five batches were run using similar coupons cut from 300 mm (12 inch) silicon wafers. The coupons were polished in each example using an SPP800S polishing tool available from Okamoto Machine Works and a MH S-15A polishing pad available from Nitta Haas Incorporated. The coupons were supported on the tool using a template type wafer head. The coupons were polished at a downforce of 1.45 psi (10 kPa), a platen rotation rate of 32 rpm, and a polishing head rotation rate of 31 rpm at a slurry flow rate of 300 ml/min (free flowing). Each batch was polished for 20 minutes.

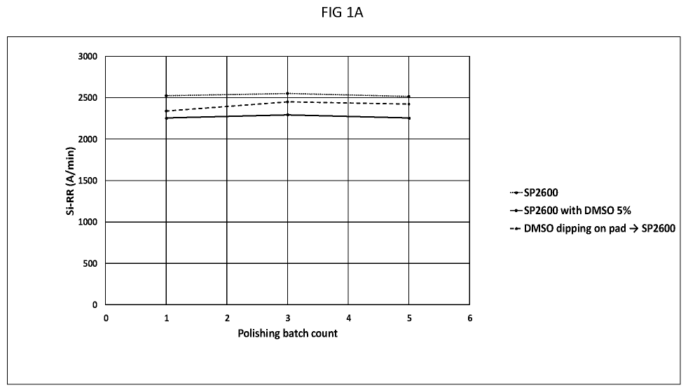

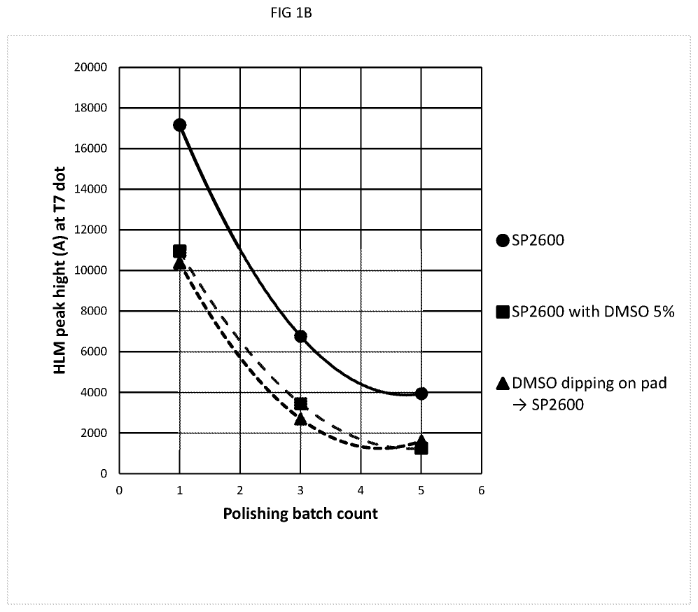

The coupons from the silicon wafers included a back side hard laser mark bar code. Upon completion of the polishing experiment, the hard laser mark peak heights and silicon removal rates were measured for the first, third, and fifth batches in each example (1A, 1B, and 1C). The peak heights were measured using a P16 stylus profiler, available from KLA-Tencor Corporation, by scanning the upper parts of the hard laser mark dots in the innermost row of the T7 mark according to SEMI standards. The maximum peak height value from the base plane on the wafer surface was taken as the HLM peak height. These HLM peak heights are set forth in Table 1 and FIG. 1A. The polishing rates were determined by weight loss measurements and are set forth Table 1 and FIG. 1B.

TABLE 1

| | Removal Rate | HLM Peak Height |
|---|---|---|
| Example-Batch | (Å/min) | (Å at T7 dot) |
| 1A-1 | 2522 | 17163 |
| 1A-3 | 2551 | 6771 |
| 1A-5 | 2515 | 3942 |
| 1B-1 | 2255 | 10949 |
| 1B-3 | 2295 | 3446 |
| 1B-5 | 2256 | 1249 |
| 1C-1 | 2340 | 10383 |
| 1C-3 | 2452 | 2697 |
| 1C-5 | 2422 | 1609 |

As is readily apparent from the results set forth in Table 1 and FIGS. 1A and 1B, the polishing composition including dimethyl sulfoxide (1B) had significantly improved flatness and reduced break-in time as indicated by the lower hard laser mark peak heights. Moreover, this improvement was achieved without a corresponding loss in Si removal rates. Nearly identical flatness and break-in time improvements were achieved via wetting the polishing pads with dimethyl sulfoxide (1C).

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
an aqueous based liquid carrier;
abrasive particles dispersed in the liquid carrier;
about 0.01 weight percent to about 2 weight percent of a dipolar aprotic solvent; and
a pH in a range from about 8 to about 12.

2. The composition of claim 1, wherein the dipolar aprotic solvent is a member of the group consisting of acetonitrile, dimethyl sulfoxide, dimethylformamide, hexamethylphosphoramide, ethyl acetate, pyridine, and mixtures thereof.

3. The composition of claim 1, wherein the dipolar aprotic solvent is dimethyl sulfoxide.

4. The composition of claim 1, comprising from about 0.05 weight percent to about 0.5 weight percent of the dipolar aprotic solvent.

5. The composition of claim 1, further comprising one or more organic carboxylic acids.

6. The composition of claim 1, further comprising one or more polyaminocarboxylic acids.

7. The composition of claim 1, further comprising one or more tetraalkylammonium salts.

8. The composition of claim 1, further comprising one or more aminophosphonic acids.

9. The composition of claim 1, further comprising one or more nitrogen containing heterocyclic compounds.

10. The composition of claim 1, wherein the abrasive particles comprise colloidal silica abrasive particles.

11. The composition of claim 10, further comprising:
one or more tetraalkylammonium salts;
one or more polyaminocarboxylic acids; and
one or more nitrogen containing heterocyclic compounds.

12. The composition of claim 11, further comprising at least one of potassium hydroxide and potassium bicarbonate.

13. The composition of claim 11, wherein the dipolar aprotic solvent is dimethyl sulfoxide.

14. A method of chemical mechanical polishing a wafer, the method comprising:
(a) contacting the wafer with a polishing composition comprising
(i) an aqueous based liquid carrier;
(ii) abrasive particles dispersed in the liquid carrier;
(iii) about 0.01 weight percent to about 2 weight percent of a dipolar aprotic solvent;
and (iv) a pH in a range from about 8 to about 12;
(b) moving the polishing composition relative to the wafer; and
(c) abrading the wafer to remove silicon from the wafer and thereby polish the wafer.

15. The method of claim 14; wherein
the method uses a polishing apparatus having (i) an upper platen and a lower platen, each of said platens having a polishing pad adhered thereto, and (ii) a carrier plate having at least one holding hole for holding the wafer; and
said abrading in (c) removes silicon from opposing first and second sides of the wafer, thereby polishing the wafer.

16. The method of claim 14, wherein:
the wafer includes a hard laser mark; and
said abrading in (c) improves a flatness of the wafer in a peripheral region of the wafer.

17. A method of polishing a silicon wafer, the method comprising:
(a) providing a polishing apparatus having at least one polishing pad mounted on a corresponding platen;
(b) contacting the polishing pad with a dipolar aprotic solvent to wet the polishing pad;
(c) contacting said wetted polishing pad with a polishing composition;
(d) moving the polishing composition relative to the wafer; and
(e) abrading the wafer to remove silicon from the wafer and thereby polish the wafer.

18. The method of claim 17, wherein the polishing composition is free of dipolar aprotic solvent.

19. The method of claim 17, wherein the dipolar aprotic solvent is dimethyl sulfoxide.

20. The method of claim 17, wherein the polishing composition comprises:
colloidal silica particles dispersed in an aqueous liquid carrier;
one or more tetraalkylammonium salts;
one or more polyaminocarboxylic acids;
one or more nitrogen containing heterocyclic compounds; and
a pH in a range from about 8 to about 12.

21. The method of claim 17, wherein:
the polishing apparatus comprises (i) an upper platen and lower platen, each of said platens having a polishing pad adhered thereto, and (ii) a carrier plate having at least one holding hole for holding the wafer; and
said abrading in (e) removes silicon from opposing first and second sides of the wafer, thereby polishing the wafer.

22. The method of claim 17, wherein:
the wafer includes a hard laser mark; and
contacting the polishing pad with the dipolar aprotic solvent in (c) and said abrading in (e) improves a flatness of the wafer in a peripheral region of the wafer.
